(19) United States
(12) Patent Application Publication
(10) Pub. No.: US 2022/0013700 A1
(43) Pub. Date: Jan. 13, 2022

(54) Method for Producing Optoelectronic Semiconductor Devices and Optoelectronic Semiconductor Device

(71) Applicant: OSRAM Opto Semiconductors GmbH, Regensburg (DE)

(72) Inventors: Pascal Porten, Regensburg (DE); Mathias Kämpf, Burglengenfeld (DE); Marcus Zenger, Hausen (DE)

(21) Appl. No.: 17/296,149

(22) PCT Filed: Dec. 4, 2019
(86) PCT No.: PCT/EP2019/083702

§ 371 Date: May 21, 2021

(30) Foreign Application Priority Data
Dec. 7, 2018 (DE) 10 2018 131 386.1

(51) Int. Cl. H01L 33/62; H01L 33/48; H01L 33/00; H01L 25/075

(52) U.S. Cl. CPC H01L 33/62; H01L 33/486; H01L 2933/0066; H01L 25/0753; H01L 33/005

(57) ABSTRACT

In one embodiment, a method includes providing a chip carrier, creating holes for electrical through-connections in the chip carrier, producing a thin metallization in the holes, filling the metallized holes with a filling of a plastic, and applying optoelectronic semiconductor chips on the metallized holes so that the semiconductor chips are ohmically conductively connected with an associated metallization, wherein a mean thickness of the metallization in the holes is between 0.1 μm and 0.7 μm, inclusive, and wherein a diameter of the holes exceeds the mean thickness of the metallization by at least a factor of 10.

This patent application is a national phase filing under section 371 of PCT/EP2019/083702, filed Dec. 4, 2019, which claims the priority of German patent application 102018131386.1, filed Dec. 7, 2018, each of which is incorporated herein by reference in its entirety.

### TECHNICAL FIELD

A method for producing optoelectronic semiconductor devices is specified. Furthermore, an optoelectronic semiconductor device is specified.

### SUMMARY

Embodiments provide a method with which small semiconductor chips can be assembled efficiently and in a space-saving manner.

According to at least one embodiment, semiconductor devices are produced with the method. The semiconductor devices are preferably optoelectronic semiconductor devices, in particular visible light-emitting semiconductor devices. In principle, however, other types of semiconductor devices can also be manufactured with the method.

According to at least one embodiment, the method comprises a step of providing a chip carrier. The chip carrier is, for example, a semiconductor wafer, made of for example of silicon or of germanium. Further, the chip carrier may be made of an electrically insulating material, such as a ceramic or a plastic. Furthermore, electrically conductive materials such as metals, for example molybdenum or aluminum, may be used for the chip carrier.

According to at least one embodiment, the method comprises a step of creating holes for electrical though-connections in the chip carrier. The holes preferably penetrate the chip carrier completely. In particular, a longitudinal axis of the holes is oriented perpendicular to a carrier top side and/or to a carrier bottom side of the chip carrier. The holes may be circular when viewed in a plan view of the chip carrier. However, other shapes for the holes are also possible, for example elongated holes or square holes or rectangular holes or oval holes as seen in a plan view.

According to at least one embodiment, the method comprises a step of producing a thin metallization in the holes. If the chip carrier is made of an electrically insulating material, the metallization may be applied directly to the chip carrier. If the chip carrier is an electrically conductive material, an electrically insulating material is preferably applied between the metallization and the chip carrier.

In particular, that the metallization is thin means that a diameter or mean diameter or a width of the holes exceeds a mean thickness of the metallization by at least a factor of 20 or 10 or 5. With other words, the metallization is significantly thinner than a width or a diameter of the holes. Thus, only a relatively small portion of the holes are filled by the metallization.

According to at least one embodiment, the method comprises a step of filling the metallized holes with a filling. The filling is preferably of an electrically insulating material. For example, the filling is a plastic filling, in particular a filling made of an epoxy material.

According to at least one embodiment, the method comprises a step of applying semiconductor chips to the metallized holes. The semiconductor chips are preferably optoelectronic semiconductor chips, such as light-emitting diode chips or laser diode chips. Furthermore, semiconductor chips can be attached as sensors for radiation. Other types of semiconductor chips, such as drive chips, memory chips or address chips, can also be attached to corresponding holes, especially if the finished semiconductor device is not an optoelectronic semiconductor device.

According to at least one embodiment, the semiconductor chips are ohmically conductively connected with the associated metallization. Between the semiconductor chips and the metallization there is preferably only an electrically conductive connection means such as a solder. By means of the metallized holes, electrical contacting of the semiconductor chips through the chip carrier is made possible.

In at least one embodiment, the method for producing optoelectronic semiconductor devices comprises the following steps, preferably in the order indicated:

A) providing a chip carrier,

B) creating holes for electrical through-connections in the chip carrier,

C) producing a thin metallization in the holes,

D) filling the metallized holes with a filling of a plastic, and

E) placing optoelectronic semiconductor chips on the metallized holes so that the semiconductor chips are ohmically conductively connected with the associated metallization.

Low-cost intermediate pieces, also known as interposers, are required for many products that include semiconductor chips. In particular, through-connections through silicon, also known as through silicon vias or TSVs for short, can be used to make electrical contact with an integrated circuit, IC for short, or a light-emitting diode chip, LED chip for short. Such through-connections are usually completely filled galvanically.

For through-connections with a relatively small aspect ratio of diameter to depth of, for example, less than 1:2 or 1:3, an alternative process to galvanic filling is desired for cost reasons. With the method described herein, electrical through-connections can be produced without electroplating and, in particular, without the material otherwise commonly used for through-connections, namely copper.

With the method described here, the placement of small LED chips on the interconnected chip carrier, i.e. the later interposer, can still be realized in a thick and thus stable state. Placing small LED chips on the finished, thin and thus mechanically fragile interposer is obsolete.

Commonly, silicon through-connections are used, which comprise holes that are completely filled with copper. In this process, the holes are completely filled galvanically with the aid of a copper electrolyte. This process can take several hours for through-connections with a small aspect ratio and is therefore comparatively expensive.

In the method described here, only sputtered metallization is preferably used instead of electroplating for the electrically conductive filling of the holes. This means that the entire holes are not filled, but only their inside is provided with a sufficiently thick but comparatively thin metal layer. However, this leaves a cavity in the metallized hole, which makes further process steps such as further lithography processes more difficult.

By filling this cavity after creating the metallic sputter lining of the inner walls of the holes, this cavity is filled with a temporary or permanent filling of a polymer. Through a targeted ashing process or wet chemical development processes, the wafer can be completely planarized. In conjunction with a temporary carrier, this allows further processing of the carrier top side and the carrier bottom side of the thinned chip carrier, enabling subsequent processes for the generation of electrical contact regions. The filling can be included in the finished semiconductor devices or can be removed in a final step, for example by means of ashing.

By using a temporary carrier, also denoted as a base carrier, processing of the thin chip carrier is still possible. Small LED chips can be placed on the carrier top side of the chip carrier even before the auxiliary carrier, which is made of silicon for example, is detached and electrically connected by means of a metallization step. A temporary adhesive on the temporary carrier preferably encloses the LED chips when the chip carrier is turned over. Thus, the LED chips are protected and buried and the temporary carrier can be removed, allowing a back side connection metallization or other electrical contact regions, such as metallization mounds, also denoted as bumps.

Thus, galvanic filling of the holes can be omitted in the method described here. By permanently or temporarily filling the holes with a plastic, the chip carrier can be further processed without contamination by lacquers, solvents or other substances of the otherwise partially hollow holes. If the filling remains permanently in the chip carrier, this increases a maximum contact area especially for the semiconductor chips. Optionally, the filling can likewise be sputtered over and thus larger metallic contact surfaces can be produced. An electrical contact surface, bumps and/or the semiconductor chips thus do not have to be placed next to the otherwise partially hollow holes, reducing a space requirement.

Furthermore, it is possible to sputter the entire surface of a layer for electrical contact regions, in particular on the carrier top side, and to subsequently structure it in order to obtain comparatively large metallic contact surfaces for light-emitting diode chips or electrical contact bumps, i.e. bumps. In particular, by placing small light-emitting diode chips before removing the temporary carrier and subsequently embedding the LED chips in an adhesive on another auxiliary carrier, it is no longer necessary to place the LED chips on the finished and thin chip carrier. This reduces the risk of breakage and eliminates the need for handling the thin chip carrier, or at least reduces such handling.

According to at least one embodiment, the semiconductor chips cover the filling after step E). The filling is preferably still present in the finished semiconductor devices.

According to at least one embodiment, a mean thickness of the metallization in the holes and/or at the carrier top side and/or at the carrier bottom side is at least 0.1 μm or 0.2 μm. Alternatively or additionally, the mean thickness of the metallization is at most 1 μm or 0.7 μm or 0.4 μm.

For example, each of the through-connections and thus each of the metallizations in the respective holes is configured for a current flow of at least 0.5 mA or 1 mA or 3 mA and/or of at most 10 mA or 5 mA. Depending on a material for the metallization and on a diameter of the holes, the thickness of the metallization is to be set accordingly. The metallization is for example made of gold, but may also additionally or alternatively be made of copper, nickel and/or silver.

According to at least one embodiment, the filling is removed, in particular before step E). That is, when the semiconductor chips are applied, the filling is no longer present. Thus, the filling is also no longer present in the finished semiconductor devices.

According to at least one embodiment, a material for the filling is applied in a liquid state in step D). The application of the material for the filling can be carried out at room temperature. Preferably, the material for the filling is applied at an elevated temperature, for example at least 70° C. or 80° C. and/or at most 100° C. A viscosity of the material for the filling can be adjusted via the temperature. The material is preferably an epoxy.

According to at least one embodiment, the material for the filling, in particular in the holes, is photochemically and/or thermally cured. If material of the filling is still present outside the holes after curing, this material outside the holes is preferably removed, for example wet-chemically or dry-chemically or, preferably, by means of ashing, for example with an O2 plasma.

According to at least one embodiment, the filling immediately after step D), together with all substeps of step D), is confined to the holes. In particular, this means that the filling is flush with the holes with a tolerance of at most 2% or 1% or 0.5% of a length of the holes. That is, no significant unevenness is formed on the chip carrier by the filling or by an absence of material of the filling at the holes, which could affect later method steps.

According to at least one embodiment, the method comprises a step A1) performed between steps A) and B). In step A1), a mask is generated on the chip carrier, in particular an oxide mask. This mask defines in step B) a shape and a position of the holes. That is, this mask can cover the chip carrier in all regions where holes are not formed. This mask is preferably still present in the finished semiconductor devices. This mask is preferably electrically insulating. For example, this mask is made of an oxide such as silicon oxide or of an electrically insulating nitride such as silicon nitride.

According to at least one embodiment, the method comprises a step B1), which is preferably performed between steps B) and C). In step Bi), a preferably continuous electrically insulating layer is produced. The insulating layer extends into the holes. Preferably, the insulating layer completely covers side surfaces of the holes. Optionally, a bottom surface of the holes is also covered by the electrical insulating layer. For example, the insulating layer is made of an oxide such as a silicon oxide or a nitride such as silicon nitride.

According to at least one embodiment, the metallization is applied directly to the insulating layer in step C). In this case, the insulating layer and the metallization can be applied congruently. Thus, the metallization preferably covers the insulating layer completely, in particular in the holes.

According to at least one embodiment, the method comprises a step H). Step H) preferably follows step E). In step H), regions of the insulating layer where the insulating layer was previously applied to the bottom surface of the holes are removed. With other words, the holes are opened. During step H), the filling is preferably still in the holes.

According to at least one embodiment, the method comprises a step D1), which preferably is carried out between steps D) and E). In step D1), electrical connection surfaces for the semiconductor chips are produced on a top side of the chip carrier. The connection surfaces are preferably formed from the metallization. That is, the metallization previously applied over the entire surface of the carrier top side is removed in regions and structured on the carrier top side to form the connection surfaces.

According to at least one embodiment, the semiconductor chips are attached to the connection surfaces by thin-film soldering in step E). A thickness of a solder between the semiconductor chips and the connection surfaces is preferably at least 0.1 μm or 0.3 μm and/or at most 2 μm or 1 μm or 0.5 μm. Alternatively or additionally, a thickness of the connection surfaces is at least 0.1 μm or 0.2 μm and/or at most 1 μm or 0.4 μm.

According to at least one embodiment, the semiconductor chips are deposited in step E) congruently or approximately congruently on the connection surfaces, as seen in a plan view of the carrier top side. Approximately means in particular with a tolerance in the direction parallel to the carrier top side of at most 25 μm or 15 μm or 5 μm. This means that the semiconductor chips can protrude laterally beyond the connection surfaces with said tolerance or vice versa.

According to at least one embodiment, a mean edge length of the semiconductor chips as seen in a plan view of the connection surfaces and/or the carrier top side is at most 60 μm. Preferably, the mean edge length of the semiconductor chips is at most 50 μm or 40 μm or 25 μm. With other words, the semiconductor chips, which are designed in particular as light-emitting diode chips, are comparatively small.

According to at least one embodiment, the mean edge length of the semiconductor chips is of the same order of magnitude as the mean diameter of the holes. In particular, this means that the mean edge length differs from the mean diameter by at most a factor of 5 or 3 or 1.5. Accordingly, the filling makes up a comparatively large proportion of an area under the semiconductor chips.

According to at least one embodiment, the method comprises a step E1) following the step E). In step E1), electrical contact regions are generated on chip top sides of the semiconductor chips facing away from the chip carrier. This is done, for example, by means of sputtering and/or by means of electroplating. These contact regions can be configured for solder mounting or for electrical contacting by means of bonding wires. A thickness of the contact regions is, for example, at least 1 μm and/or at most 10 μm or 5 μm.

According to at least one embodiment, the method comprises a step F) following step E). In step F), the mounted semiconductor chips are embedded in a fastening means and are attached to a temporary auxiliary carrier by means of the fastening means. The fastening means is preferably an adhesive. The adhesive can be removed from the semiconductor chips chemically or thermally, in particular without leaving any residue. The fastening means is no longer present in the finished semiconductor devices. The temporary auxiliary carrier is made of glass or a plastic, for example. The temporary auxiliary carrier can be mechanically rigid or also mechanically flexible, i.e. designed as a film.

According to at least one embodiment, the chip carrier is located on a base carrier in steps A) to E) or in steps A) to F). The base carrier is preferably mechanically rigid and made, for example, of silicon. Between the chip carrier and the base carrier there is a connection means layer, preferably a metallic connection means layer such as a solder.

According to at least one embodiment, the base carrier is removed in a step G) after the step F). This is done, for example, thermally or chemically by etching or mechanically.

According to at least one embodiment, the method comprises a step I). Step I) follows step F). In step I), contact metallizations are produced on sides of the holes facing away from the semiconductor chips in each case. The contact metallizations are configured for external electrical contacting of the finished semiconductor devices. The contact metallizations preferably cover the holes completely. Preferably, the contact metallizations are made of the same material as the metallizations in the holes.

The contact metallizations can be applied directly to the respective filling of the holes. The contact metallizations are produced, for example, by means of sputtering and/or by means of electroplating. The contact metallizations may be provided for solder mounting or for electrical contacting by means of bonding wires. A thickness of the contact metallizations is, for example, at least 1 μm and/or at most 10 μm or 5 μm.

According to at least one embodiment, the contact metallizations partially extend into the holes. A region in which the contact metallizations extend into the holes preferably comprises only a small depth, for example at most 0.5 μm or 0.2 μm. Alternatively or additionally, it is possible that the contact metallizations rise above the holes. For example, the contact metallizations rise above the holes to at least 0.2 μm or 0.5 μm and/or to at most 10 μm or 5 μm or 1 μm.

According to at least one embodiment, in a step J) a separation through the chip carrier is performed so that a size of the semiconductor devices is determined. Step J) is preferably carried out after step E). Alternatively, step J) can also be carried out after or with step B).

The individual steps mentioned for the method are preferably carried out one after the other according to their alphabetical enumeration. In the event that all method steps are carried out, the sequence is therefore as follows: A), A1), B), B1), C), D), D1), E), E1), F), G), H), I), J).

According to at least one embodiment, the semiconductor chips are designed as flip chips. In this case, the semiconductor chips preferably each cover several of the holes designed as through-connections, for example two of the holes. Accordingly, electrical contacting of the semiconductor chips in the finished semiconductor devices takes place exclusively via the carrier bottom side.

Furthermore, an optoelectronic semiconductor device is specified. The semiconductor device is particularly preferably produced with a method according to one or more of the embodiments mentioned above. Features of the method are therefore also disclosed for the semiconductor device, and vice versa.

In at least one embodiment, the semiconductor device comprises a chip carrier with at least one hole. A thin metallization is formed on side walls of the hole and on a carrier top side of the chip carrier. Electrical connection surfaces are formed on the carrier top side by the metallization. A filling made of a plastic is located in the hole, so that the filling fills the metallization and thus the hole. At least one optoelectronic semiconductor chip is mounted on the hole and on the connection surface, so that an electrical through-connection for the semiconductor chip is formed through the chip carrier by the metallization in the hole. The semiconductor chip comprises a mean edge length of at most 60 μm or 40 μm as viewed in a plan view of the carrier top side.

### BRIEF DESCRIPTION OF THE DRAWINGS

In the following, a method described herein and an optoelectronic semiconductor device described herein are explained in more detail with reference to the drawing by means of exemplary embodiments. Identical reference signs specify identical elements in the individual figures. However, no references to scale are shown, rather individual elements may be shown exaggeratedly large for better understanding.

FIGS. 1 to 22 show schematic sectional views of method steps of an exemplary embodiment of a method described herein;

FIG. 23 shows a schematic sectional view of a method step of an exemplary embodiment of a method described herein;

FIGS. 24 and 25 show schematic sectional views of exemplary embodiments of optoelectronic semiconductor devices described herein; and

FIGS. 26 and 27 show schematic plan views of exemplary embodiments of optoelectronic semiconductor devices described herein.

### DETAILED DESCRIPTION OF ILLUSTRATIVE EMBODIMENTS

FIGS. 1 to 22 illustrate an exemplary embodiment of a method described herein. According to FIG. 1, a wafer 13′ is provided for a chip carrier 13. The wafer 13′ is preferably made of silicon.

For mechanical stabilization, the wafer 13′ is mounted on a base carrier 11. The base carrier 11 is also preferably made of silicon. A connection between the base carrier 11 and the wafer 13′ is made via a connection means 12, which is preferably a solder.

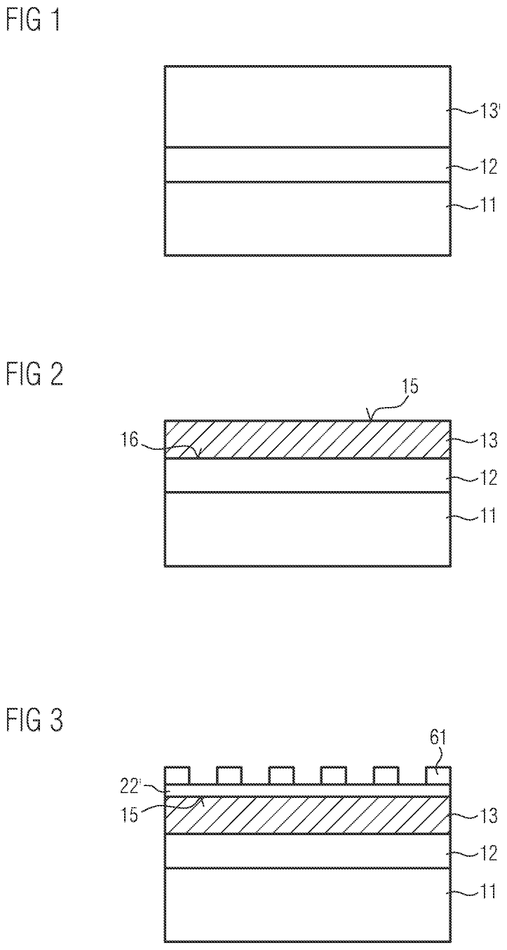

In FIG. 2 it is illustrated that the wafer 13′ is brought to a desired thickness so that the chip carrier 13 is formed. A carrier top side 15 of the chip carrier 13 faces away from the base carrier 11, and a carrier bottom side 16 is located directly on the connection means 12. A thickness of the chip carrier 13 is preferably at least 40 μm or 55 μm and/or at most 200 μm or 150 μm or 100 μm. The chip carrier 13 forms a so-called interposer in order to adjust a desired thickness of the finished semiconductor devices 1.

In the step of FIG. 3, a material 22′ for an oxide mask 22 is continuously applied to the carrier top side 15. The material of the oxide mask 22 is preferably silicon dioxide. It can also be seen in FIG. 3 that a first mask layer 61, preferably made of a photoresist, is applied and patterned onto the oxide mask 22.

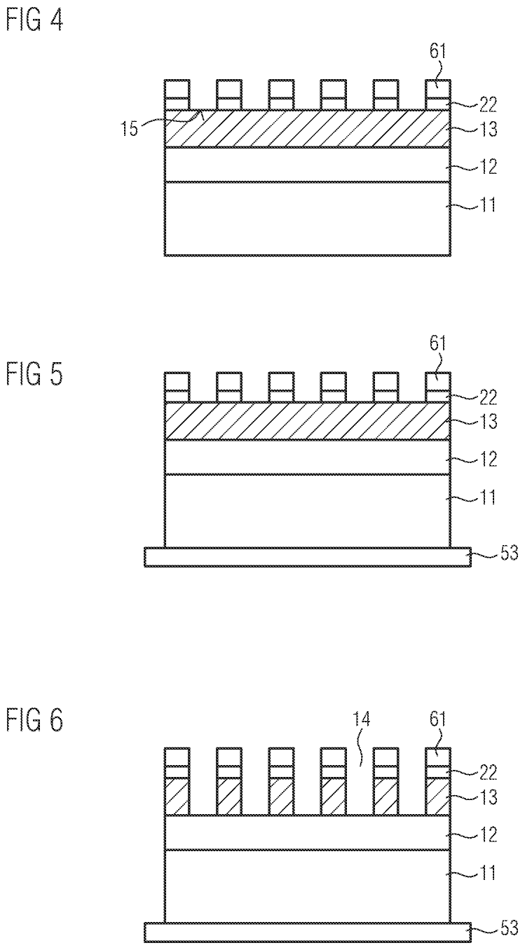

In the step of FIG. 4, the oxide mask 22 is generated. In this step, the first mask layer 61 is used for structuring, thus exposing the carrier top side 15 in places.

In the optional step of FIG. 5, a base foil 53 is attached to the base carrier 11. The base foil 53 is preferably extensible.

According to FIG. 6, holes 14 are produced through the chip carrier 13. A position and a shape of the holes 14 are defined by the oxide mask 22, as seen in a plan view of the carrier top side 15. The holes 14 extend to the connection means 12 and thus completely penetrate the chip carrier 13.

According to FIG. 6, only the holes 14 are created through the chip carrier 13. Furthermore, according to FIG. 6, no separation of the carrier 13 into regions for later semiconductor devices 1 takes place. Alternatively, a structuring of the chip carrier 13 to the later semiconductor devices 1 can already take place in a step corresponding to FIG. 6. This is shown in FIG. 23. The individual segments or parts of the chip carrier 13, which are optionally still on the base carrier 11, can each comprise one of the holes 14 or several of the holes 14.

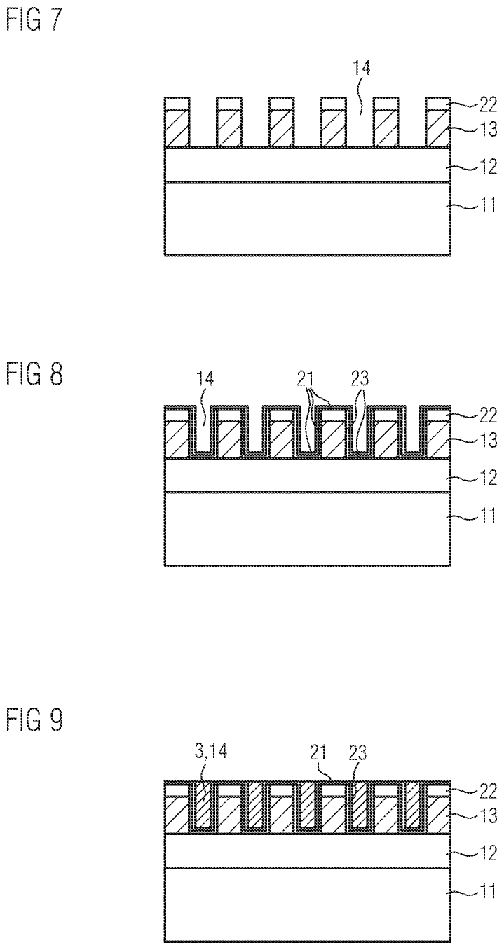

In the step of FIG. 7, the first mask layer 61 is removed. Alternatively, it is possible to remove the first mask layer 61 already at the step of FIG. 5.

In the step of FIG. 8, an electrically insulating layer 23 is first applied. The insulating layer 23 is preferably made of an oxide, in particular silicon dioxide. Thus, the insulating layer 23 may be produced by means of oxidation of the material of the chip carrier 13, as may be the case for the oxide mask 22. A thickness of the insulating layer 23 and/or the oxide mask 22 is, for example, at least 50 nm or 100 nm and/or at most 500 nm or 250 nm.

The insulating layer 23 preferably immediately adjoins the oxide mask 22. If the insulating layer 23 is not produced from material of the chip carrier 13, as can likewise be the case for the oxide mask 22, but for example via sputtering or via chemical vapor deposition, the insulating layer 23 preferably covers the chip carrier 13 and also the oxide mask 22 as a continuous, uninterrupted layer.

Subsequently, as also shown in FIG. 8, a metallization 21 is preferably produced over the entire surface. The metallization 21 extends into the holes 14 and completely covers the insulating layer 23 on the side surfaces of the holes 14 and also on a bottom side of the holes 14 on the connection means 12.

Preferably, the metallization 21 is produced by sputtering. A thickness of the metallization 21 is, for example, between 200 nm and 500 nm inclusive. Preferably, the metallization 21 is made of gold.

In FIG. 9, it is shown that a filling 3 is brought into the holes 14. The filling 3 completely fills the holes 14. The filling 3 is preferably made of a plastic, in particular an epoxy.

In FIG. 9, only the finished filling 3 is illustrated. To produce the filling 3, a material for the filling 3 is preferably applied over the entire surface in a liquid state in a first sub-step and subsequently cured in a second sub-step. Superfluous material for the filling 3 outside the holes 14 is then removed in a third sub-step so that the filling 3 is flush with the holes 14, in particular flush with the previously applied metallization 21.

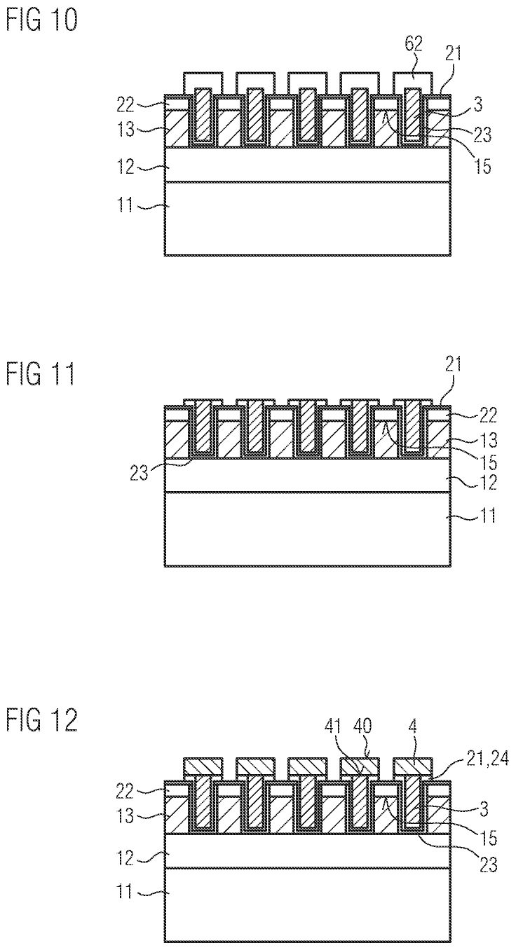

In the step of FIG. 10, a second mask layer 62 is applied, in particular of a photoresist. The second mask layer 62 completely covers the holes 14 and thus the filling 3. The metallization 21 on the carrier top side 15 is only partially covered by the second mask layer 62.

According to FIG. 11, the metallization 21 is structured so that several electrical connection surfaces 24 are formed on the carrier top side 15. The connection surfaces 24 preferably extend in a frame shape around the associated holes 14 with the filling 3, as seen in a plan view of the carrier top side 15. It is possible that there is a one-to-one correspondence between the connection surfaces 24 on the carrier top side 15 and the holes 14. Alternatively, a plurality of the holes 14 may be collectively enclosed by a single connection surface 24.

A distance between adjacent connection surfaces 24 in a direction parallel to the carrier top side 15 is, for example, at least 10 μm or 20 μm and/or at most 100 μm or 50 μm or 20 μm.

Different than the illustration in FIG. 11, it is optionally possible that an additional metal layer is generated after the step of FIG. 9, so that the metallization 21 can also extend over the filling 3. The connection surfaces 24 then completely cover the filling 3 and do not only extend around the filling 3.

In the step of FIG. 12, semiconductor chips 4 are applied to the connection surfaces 24. The semiconductor chips 4, which are preferably light emitting diode chips, completely cover the associated filling 3. The semiconductor chips 4 are attached to the associated connection surfaces 24 preferably by means of thin-film soldering.

The semiconductor chips 4 each comprise a chip top side 40 facing away from the chip carrier 13. Chip bottom sides 41 face the chip carrier 13. The chip top sides 40 are preferably main radiation sides of the semiconductor chips 4. The chip top sides 40 are preferably approximately congruent over the connection surfaces 24.

The semiconductor chips 4 are preferably small and, viewed in a plan view of the carrier top side 15, comprise, for example, mean edge lengths in the range around 50 μm or around 20 μm.

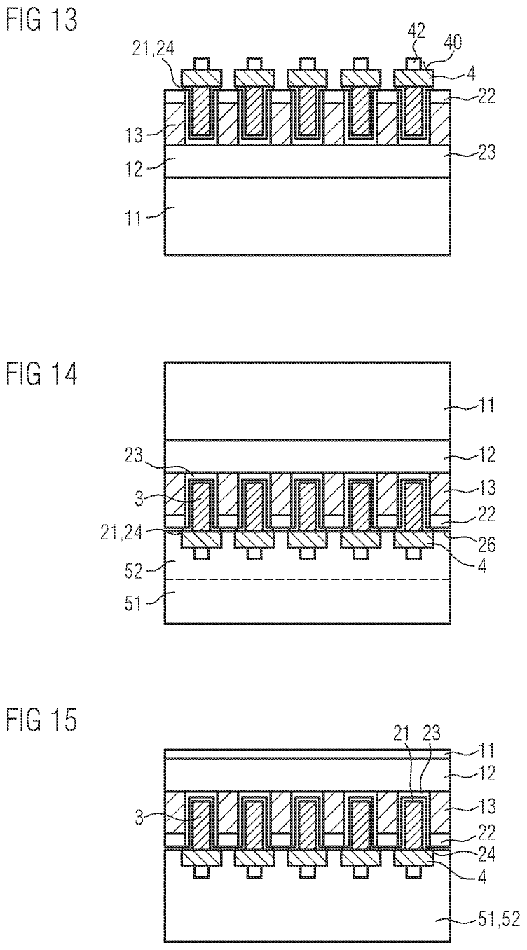

According to FIG. 13, electrical contact regions 42 are created on the chip top sides 40 of the semiconductor chips 4. The contact regions 42 are preferably made of at least one metal and are configured, for example, for bonding wire contacting or for soldering to a carrier which is transparent, for example, and is not shown.

In the step of FIG. 14 the chip carrier 13 is turned over. The semiconductor chips 4 with the contact regions 42 are embedded in a fastening means 52. The fastening means 52 is an adhesive. Thus the chip carrier 13 is fastened to an auxiliary carrier 51. The auxiliary carrier 51 is preferably rigid and made, for example, of a glass or also of silicon. The temporary fastening means 52 can subsequently be removed from the semiconductor chips 4, for example, by radiation or temperature increase.

According to FIG. 14, a gap 26 is present between the fastening means 52 and the oxide mask 22. Deviating from this, the fastening means 52 can also extend directly to the oxide mask 22, so that no gap 26 is then present.

In the step shown in FIG. 15, the base carrier 11 is partially removed, for example by grinding. Thus, only a thin layer of the base carrier 11 remains over the connection means 12. This thin layer has, for example, a thickness of at least 2 μm and/or of at most 20 μm. Previously, the base carrier 11 is preferably at least 150 μm and/or at most 2 mm thick.

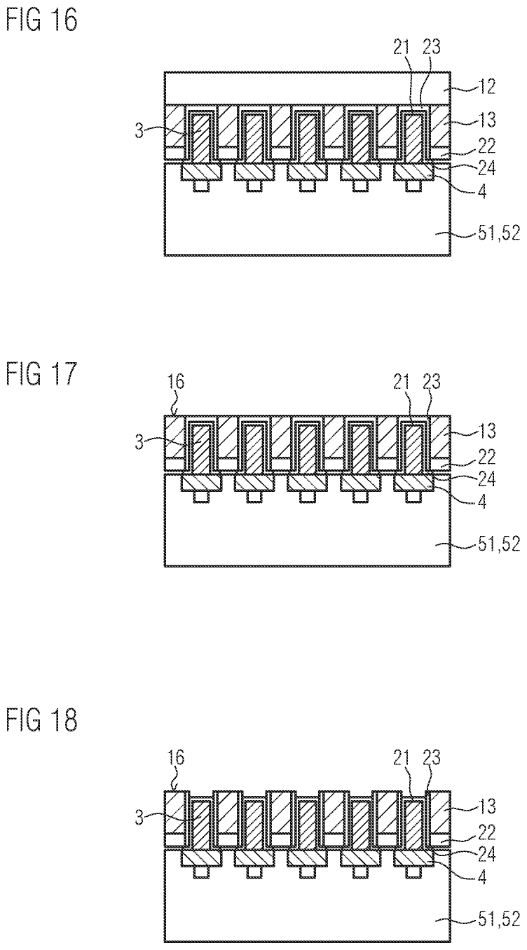

In the step of FIG. 16, it is shown that the base carrier 11 has been completely removed, for example by means of plasma etching or wet chemical etching. A corresponding etching process stops at the metallic connection means layer 12.

Referring to FIG. 17, the connection means 12 is completely removed to expose the bottom side 16 of the carrier. On surfaces that were formerly bottom surfaces of the holes 14 facing the connection means 12, the insulating layer 23 is thus also exposed.

Optionally, the steps of FIGS. 15 to 17 can also be carried out in a single step, so that the base carrier 11 is removed together with the connection means 12 in a common step, for example via a thermal method and/or via an etching method.

In the step of FIG. 18, it is shown that regions of the insulating layer 23 which lie in a plane with the carrier bottom side 16 are removed. This exposes the metallization 21 on the former bottom side of the holes 14.

Deviating from the illustration in FIG. 18, it is also possible that the insulating layer 23 is removed by dry chemical means. In this case, a thin layer of the chip carrier 13 may also be removed, so that the carrier bottom side 16 is then flush or almost flush with the metallization 21.

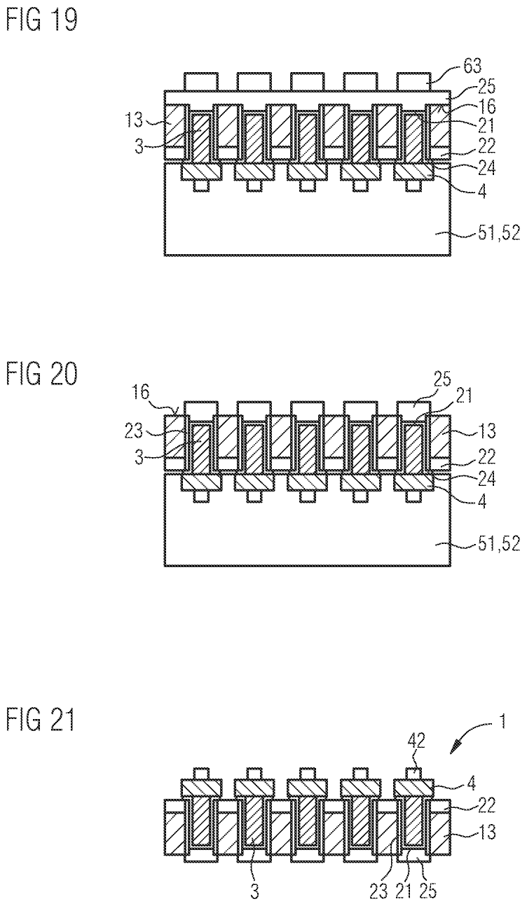

According to FIG. 19, a preferably continuous layer for contact metallization 25 is deposited on the carrier bottom side 16. The contact metallization 25 is produced by sputtering and optionally additionally by electroplating. The contact metallization 25 is, for example, made of the same material as the metallization 21, i.e. in particular of gold.

Furthermore, it can be seen in FIG. 19 that a third mask layer 63 is applied, in particular made of a photoresist.

According to FIG. 20, the metallic layer applied in FIG. 19 is structured to the contact metallizations 25. This structuring is carried out on the basis of the third mask layer 63. The third mask layer 63 is subsequently removed.

The layer for the contact metallizations 25 is structured in each case to form islands which are confined to the holes 14 with the filling 3. Alternatively, it is possible that this layer is also structured to form conductor tracks, in particular if there are several semiconductor chips 4 which are to be electrically connected. The same can apply to the connection surfaces 24 on the carrier top side 15.

According to FIG. 21, the auxiliary carrier 51 and the fastening means 52 are removed so that the chip carrier 13 functions as the supporting element of the semiconductor device 1. A thickness of the semiconductor device 1 can be set via the chip carrier 13, wherein the thickness has already been defined in the step shown in FIG. 2.

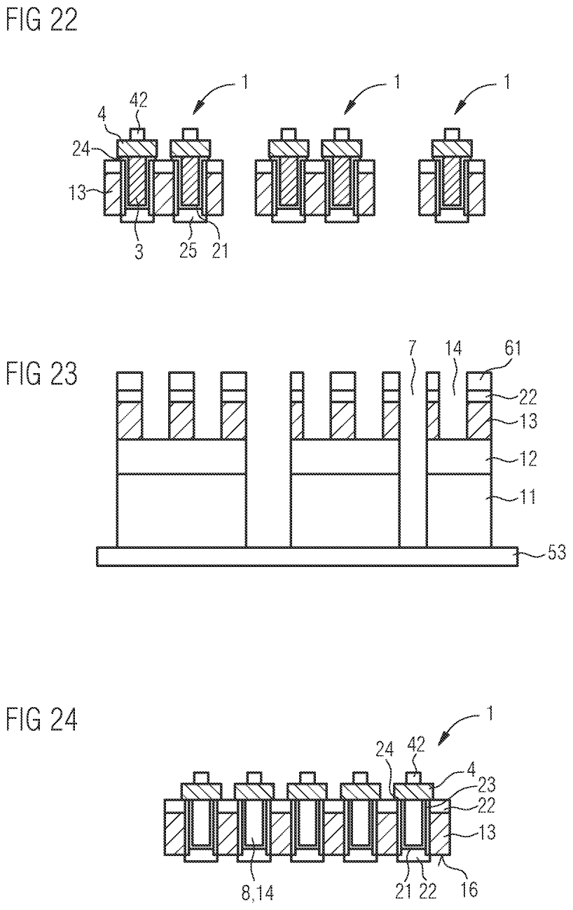

In the optional step of FIG. 22, a separation into smaller semiconductor devices 1 is carried out. The semiconductor devices 1 can each comprise one or more of the semiconductor chips 4.

FIG. 24 shows another exemplary embodiment of the semiconductor device 1. In this exemplary embodiment, the filling 3 is not present, so that cavities 8 are formed in each of the holes 14 at the metallization 21.

In order to obtain the semiconductor device 1 of FIG. 24, the method steps of FIGS. 1 to 21 can be carried out in substantially the same way, wherein, however, the semiconductor chips 4 are applied between the steps of FIGS. 20 and 21. The filling 3 is thus preferably removed after the step of FIG. 20 and after the auxiliary carrier 51 and the fastening means 52 have been detached, whereupon the semiconductor chips 4 are mounted.

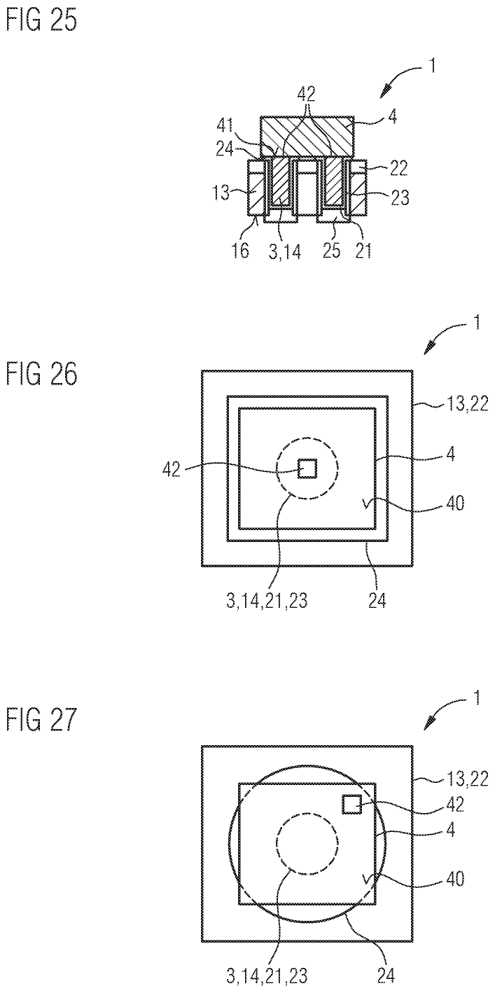

In FIG. 25 it is illustrated that the semiconductor chips 4 are designed as flip chips. Thus, all electrical contact regions of the semiconductor chips 4 are located at the chip bottom side 41, which faces the chip carrier 13. The semiconductor chips 4 thus each cover several of the holes 14 designed as through-connections. Again, the filling 3 is preferably present.

In FIG. 26 it is illustrated that the semiconductor chips 4 are mounted approximately congruently on the associated connection surface 24 of the chip carrier 13. The connection surfaces 24 extend in a frame-like manner completely around the associated hole 14. For example, the holes 14 are circular when viewed from above, whereas the connection surfaces 24 may be square or rectangular in shape. Preferably, the holes 14 are located centrally in the respective connection surface 24, but may also be accommodated at an edge of the connection surface 24, in deviation from the representation of FIG. 26. The electrical contact region 42 may be located centrally in the chip top surface 40.

In deviation from the illustration of FIG. 26, the semiconductor chip 4 may also be larger than the connection surface 24 and thus project beyond the connection surface 24 all around or on at least some sides.

In FIG. 27 it is illustrated that the hole 14 and the associated connection surface 24 comprise the same basic geometric shape, for example comprise a circular outer contour. The connection surface 24 thus extends in a circular ring shape around the associated hole 14. The semiconductor chip 4 thus projects laterally in places beyond the connection surface 24, and vice versa.

Unless otherwise indicated, the components shown in the figures preferably follow each other directly in the sequence indicated. Layers not touching in the figures are preferably spaced apart. Insofar as lines are drawn parallel to each other, the corresponding surfaces are preferably also aligned parallel to each other. Likewise, unless otherwise indicated, the relative positions of the drawn components to each other are correctly reproduced in the figures.

The invention described here is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1.-17. (canceled)

18. A method for producing optoelectronic semiconductor devices, the method comprising:
providing a chip carrier,
creating holes for electrical through-connections in the chip carrier,
producing a thin metallization in the holes;
filling the metallized holes with a filling of a plastic; and
applying optoelectronic semiconductor chips on the metallized holes so that the semiconductor chips are ohmically conductively connected with an associated metallization,
wherein a mean thickness of the metallization in the holes is between 0.1 μm and 0.7 μm, inclusive, and
wherein a diameter of the holes exceeds the mean thickness of the metallization by at least a factor of 10.

19. The method according to claim 18, wherein the semiconductor chips cover the filling, and wherein the filling is still present in finished semiconductor devices.

20. The method according to claim i8, further comprising:
removing the filling before applying the optoelectronic semiconductor chips.

21. The method according to claim 18,
wherein filling the metallized holes comprises filling the metallized holes with a material in a liquid state, and
wherein the material is subsequently photochemically and/or thermally cured in the holes.

22. The method according to claim 18, wherein filling the metallized holes comprises:
applying the filling over an entire surface; and
subsequently planarizing the filling so that the filling is confined to the holes and is flush with the holes with a tolerance of at most 2% of a length of the holes.

23. The method according to claim 18, further comprising:
generating an oxide mask on the chip carrier thereby defining shapes of the holes, wherein the oxide mask is still present in finished semiconductor devices.

24. The method according to claim 18, further comprising:
forming a continuous electrical insulating layer which extends into the holes and completely covers a bottom surface of the holes,
wherein the metallization is directly applied to the insulating layer.

25. The method according to claim 24, further comprising:
removing regions of the insulating layer where the insulating layer was previously applied to the bottom surface of the holes after applying the optoelectronic semiconductor chips.

26. The method according to claim 18, further comprising:
forming electrical connection surfaces for the semiconductor chips on a carrier top side of the chip carrier before applying the optoelectronic semiconductor chips,
wherein the semiconductor chips are mounted on the connection surfaces by thin-film soldering, and
wherein the connection surfaces have a thickness between 0.1 μm and 1 μm, inclusive.

27. The method according to claim 26,
wherein applying the optoelectronic semiconductor chips comprises applying the optoelectronic semiconductor chips congruently to the connection surfaces with a tolerance of at most 15 μm, and
wherein, viewed in a plan view of the connection surfaces, a mean edge length of the semiconductor chips is at most 60 μm.

28. The method according to claim 18, further comprising:
forming electrical contact regions on chip top sides of the semiconductor chips facing away from the chip carrier.

29. The method according to claim 18, further comprising:
embedding the mounted semiconductor chips in a fastening means, wherein the mounted semiconductor chips are attached to a temporary auxiliary carrier by the fastening means.

30. The method according to claim 29,
wherein the chip carrier is located on a base carrier and is fastened to the base carrier by a metallic connection means layer,
wherein the base carrier is removed after embedding the mounted semiconductor chips, and
wherein contact metallizations for external electrical contacting of finished semiconductor devices are produced on sides of the holes facing away from the semiconductor chips in each case.

31. The method according to claim 30, wherein the contact metallization extends partially into the holes so that the contact metallization rises above the holes.

32. The method according to claim 18, further comprising:
performing separation through the chip carrier to the semiconductor devices,
wherein separation is performed either after applying the optoelectronic semiconductor chips or before creating the holes.

33. The method according to claim 18, wherein the semiconductor chips are designed as flip chips.

34. An optoelectronic semiconductor device manufactured according to the method of claim 18, the semiconductor device comprising:
a chip carrier with at least one hole;
a thin metallization on side walls of the hole and on a carrier top side of the chip carrier so that an electrical connection surface is formed on the carrier top side;
a filling of a plastic in the hole so that the filling fills the metallization and thus the hole; and
at least one optoelectronic semiconductor chip on the hole and on the connection surface such that an electrical through-connection for the semiconductor chip is formed through the chip carrier by the metallization in the hole,
wherein the semiconductor chip has a mean edge length of at most 60 μm when viewed in a plan on the carrier top side.

35. A method for producing optoelectronic semiconductor devices, the method comprising:
providing a chip carrier;
creating holes for electrical through-connections in the chip carrier;
generating a continuous electrical insulating layer which extends into the holes and completely covers a bottom surface of the holes;
producing a thin metallization in the holes and applying the metallization directly to the electrical insulting layer;
filling the metallized holes with a filling of a plastic; and
applying optoelectronic semiconductor chips on the metallized holes so that the semiconductor chips are ohmically conductively connected with an associated metallization.
